(19) United States
(12) Patent Application Publication
(10) Pub. No.: US 2025/0357857 A1
(43) Pub. Date: Nov. 20, 2025

(54) SWITCHED CAPACITOR POWER SOURCE CIRCUIT

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Keisuke TANIGUCHI, Nisshin-shi (JP); Yoshikazu FURUTA, Nisshin-shi (JP); Tomohiro NEZUKA, Nisshin-shi (JP); Shigeki OTSUKA, Nisshin-shi (JP)

(21) Appl. No.: 19/204,902

(22) Filed: May 12, 2025

(30) Foreign Application Priority Data
May 15, 2024 (JP) 2024-079463
Apr. 4, 2025 (JP) 2025-062477

(51) Int. Cl. H02M 3/07; H02M 3/00; H10D 86/00; H10D 86/80

(52) U.S. Cl. CPC H02M 3/072; H02M 3/003; H10D 86/201; H10D 86/80

(57) ABSTRACT

A switched capacitor power source circuit includes: an integrated circuit for converting an input voltage into a predetermined output voltage by charging and discharging a plurality of capacitance elements via a plurality of switching elements using a plurality of clock signals with different phases. A well layer disposed under each of the capacitance elements is connected via a load circuit to a point of potential equal to or lower than a potential of a semiconductor substrate constituting the integrated circuit.

### CROSS REFERENCE TO RELATED APPLICATION

The present application claims the benefit of priority from Japanese Patent Applications No. 2024-079463 filed on May 15, 2024 and No. 2025-062477 filed on Apr. 4, 2025. The entire disclosure of the above application is incorporated herein by reference.

### TECHNICAL FIELD

The present disclosure relates to a switched capacitor power source circuit.

### BACKGROUND

In recent years, there has been a demand for technological development of a high step-down ratio DC/DC converter that converts electric power from a high voltage power source of 400V or more, such as an in-vehicle battery, to a low voltage power source of about 12V. In order to achieve high conversion efficiency, such DC/DC converters often use switching power sources using a transformer. When performing electric power conversion at a high step-down ratio, however, it is necessary to reduce the duty ratio of the PWM signal. In other words, as the control signal becomes a narrower pulse, the difficulty of timing design may increase and the conversion efficiency may be reduced. In addition, transformers are generally large and heavy. Because such switching power sources are not suitable for achieving high step-down ratios or for achieving compact size, switched-capacitor power sources implemented only with capacitance and switches have been attracting attention.

### SUMMARY

According to an example, a switched capacitor power source circuit may include: an integrated circuit for converting an input voltage into a predetermined output voltage by charging and discharging a plurality of capacitance elements via a plurality of switching elements using a plurality of clock signals with different phases. A well layer disposed under each of the capacitance elements is connected via a load circuit to a point of potential equal to or lower than a potential of a semiconductor substrate constituting the integrated circuit.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a diagram showing a configuration of a switched capacitor power source circuit according to a first embodiment;

FIGS. 2A to 2C are diagrams showing a cross-sectional view, an equivalent circuit and a capacitance symbol of a schematic semiconductor configuration of a capacitance element;

FIGS. 3A to 3B are diagrams showing a cross-sectional view and an equivalent circuit of a schematic semiconductor configuration of a capacitance element according to a comparison example;

FIG. 4 is a diagram showing a simulation result;

FIG. 5 is a diagram showing a configuration of a switched capacitor power source circuit according to a second embodiment;

FIG. 6 is a diagram showing a configuration of a switched capacitor power source circuit according to a third embodiment;

FIGS. 7A to 7C are diagrams showing the configuration, a capacitance symbol and a clock timing of a Dickson star type switched capacitor power source circuit according to a comparison example;

FIG. 8 is a diagram showing a connection state in phase 1 when the switch S2 is at a high level;

FIG. 9 is a diagram showing a connection state in phase 2 when the switch S1 is at a high level;

FIG. 10 is a diagram showing the configuration of a LADDER type switched capacitor power source circuit according to a comparison example;

FIG. 11 is a diagram showing a connection state in phase 1 when the switch S2 is at a high level; and

FIG. 12 is a diagram showing a connection state in phase 2 when the switch S1 is at a high level.

### DETAILED DESCRIPTION

The present embodiments provide a switched capacitor power source circuit that is formed by an integrated circuit, charges and discharges a plurality of capacitance elements via a plurality of switching elements in response to a plurality of clock signals with different phases, and converts an input voltage into a predetermined output voltage.

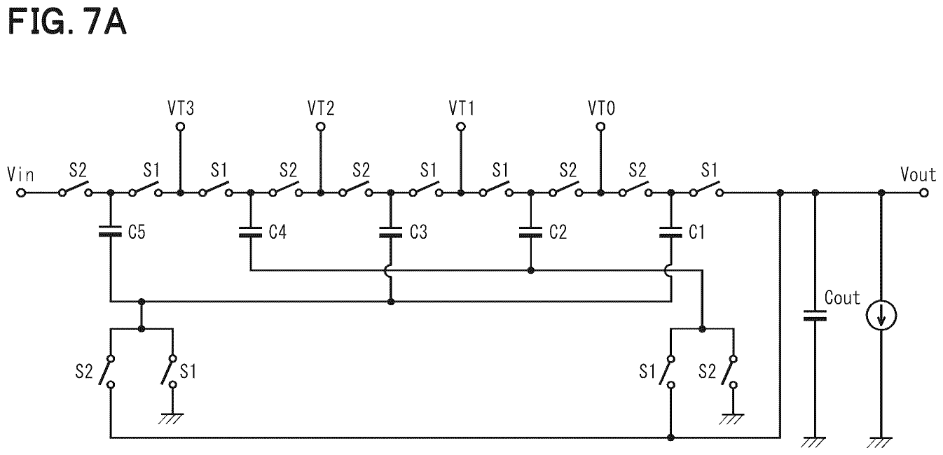

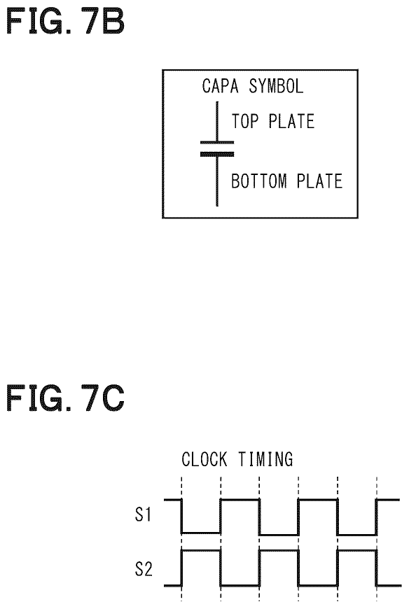

For example, a conceivable technique proposes a fully integrated switched-capacitor power source circuit with a Dickson star topology. When a switched capacitor power source circuit is configured as an integrated circuit, a so-called BOX capacitance is generated as a capacitive component in a BOX (i.e., Buried-Oxide) layer located below the capacitance element. Since this BOX capacitance is connected in series to the capacitance element, the power conversion efficiency of the switched capacitor power source circuit is reduced. This feature will be described with reference to FIGS. 7A to 12. In these drawings, S1 and S2 represent clock signals having different phases and switches driven by the respective clock signals.

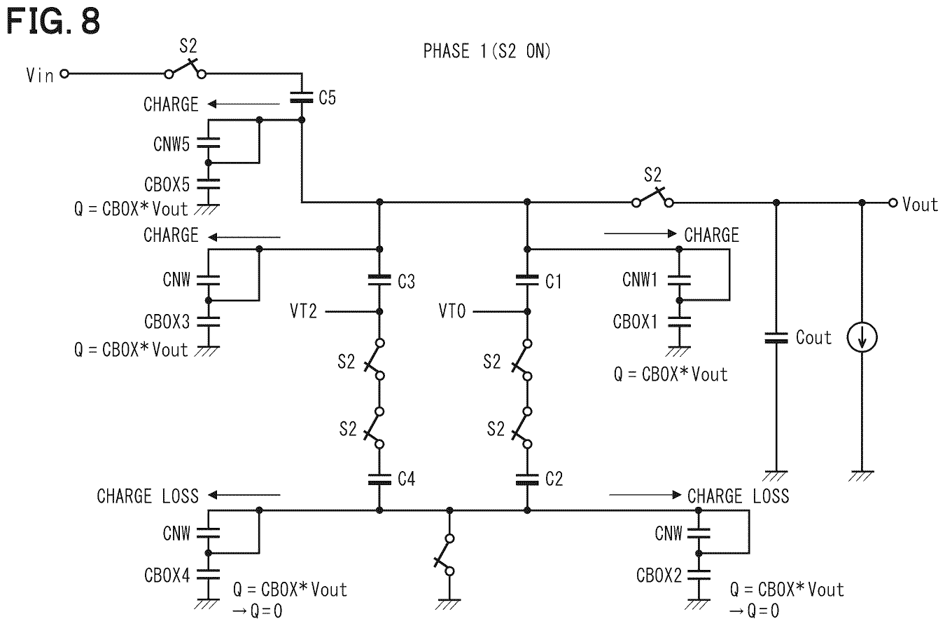

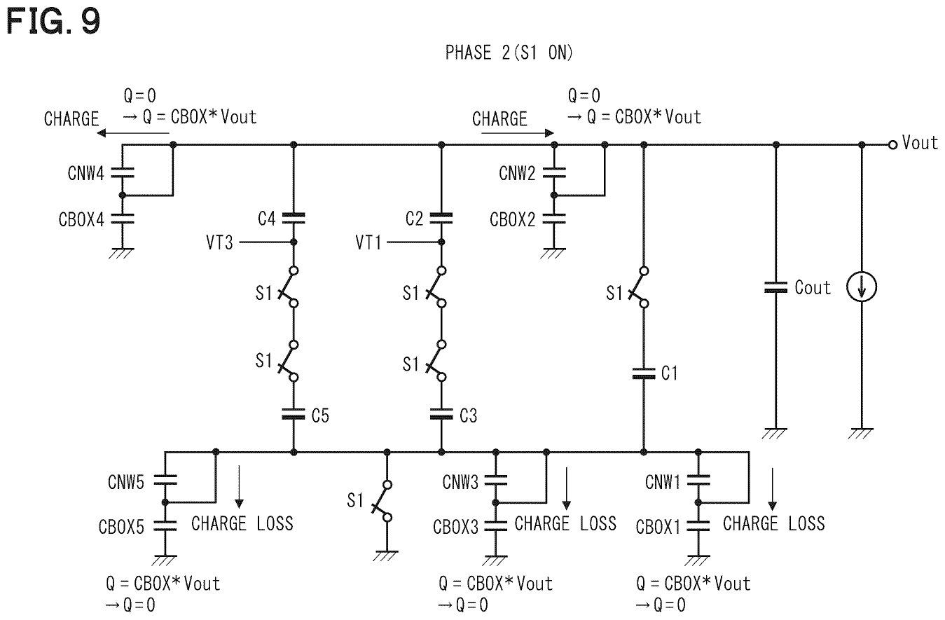

FIGS. 7A to 7C show a Dickson star type switched capacitor power source circuit. As shown in FIG. 8, in phase 1 in which the switch S2 is at a high level, the BOX capacitance CBOX is charged by the output voltage Vout via the capacitance elements C1, C3, and C5. At this time, the bottom plates of the capacitance elements C2 and C4 are connected to the ground, so that the charges stored in these BOX capacitances CBOX are discharged, resulting in a loss. Also, as shown in FIG. 9, in phase 2 in which the switch S1 becomes a high level, the BOX capacitance CBOX is charged by the output voltage Vout via the capacitance elements C2 and C4, and the charge stored in the BOX capacitance CBOX of the capacitance elements C1, C3, and C5 is discharged, resulting in a loss.

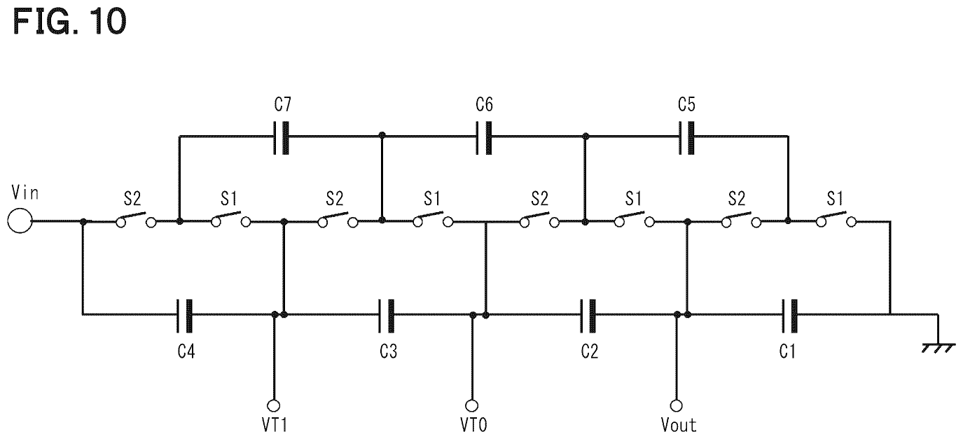

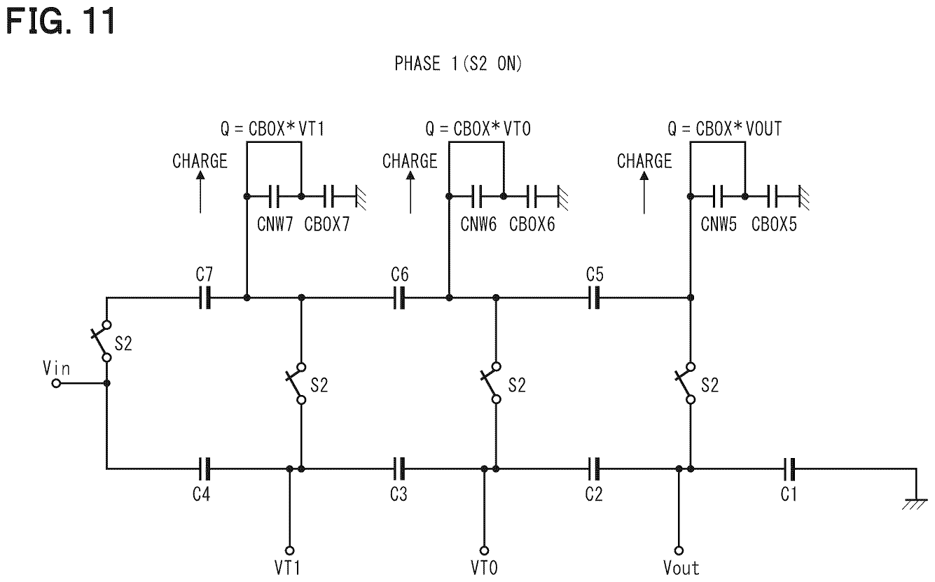

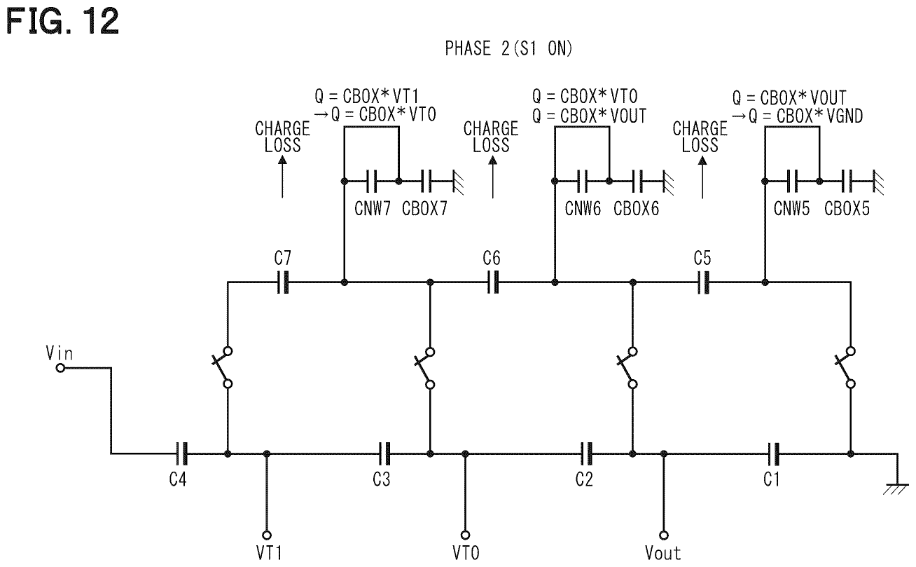

FIG. 10 shows a LADDER type switched capacitor power source circuit. As shown in FIG. 11, in phase 1 in which the switch S2 is at a high level, each BOX capacitance CBOX is charged via the capacitance elements C5, C6, and C7 with the output voltage Vout, the voltage VT0 at the common connection point of capacitance elements C2 and C3, and the voltage VT1 at the common connection point of capacitance elements C3 and C4, respectively. Also, as shown in FIG. 12, in phase 2 in which the switch S1 becomes a high level, the charge stored in the BOX capacitance CBOX5 is discharged, the BOX capacitance CBOX6 is charged with the output voltage Vout, and the BOX capacitance CBOX7 is charged with the voltage VT0.

In this way, the difference ΔQ in the charge of each BOX capacitance between phase 1 and phase 2 becomes a loss. Specifically, expressions of “VT1=3×VOUT”, and “VT0˜2×VOUT” are satisfied.

Thus, an expression of “C5: ΔQ5=CBOX(Vout−GND)˜CBOX×Vout” is established. An expression of “C6: ΔQ6=CBOX(VT0−Vout)˜CBOX×Vout” is established. An expression of “C7: ΔQ7=CBOX(VT1−VT0)˜CBOX×Vout” is established. An expression of “ΔQ=ΔQ5+ΔQ6+ΔQ7” is established.

FIG. 12 of Non-Patent Literature 1 teaches a configuration that employs a special process to form an n-Buried layer on a p-substrate layer and apply a high voltage as a countermeasure against the BOX capacitance.

However, in the countermeasure such as that in the conceivable technique, the circuit area increases due to the addition of an n-Buried layer, which increases the manufacturing cost.

The present disclosure has been made in view of the above circumstances, and an object of the present embodiments is to provide a switched capacitor power source circuit capable of reducing the BOX capacitance even when an integrated circuit is formed by a general-well-known process.

According to the switched capacitor power source circuit of the first aspect, the well layer arranged below the capacitance elements in the integrated circuit is connected to a potential point lower than the potential of the semiconductor substrate via the load circuit. It should be noted that the term “load circuit” refers to a circuit that has at least a resistance component, and includes a single element. Here, the capacitance of the well layer in the capacitance element is defined as C_{W}, the BOX capacitance is defined as C_{BOX}, and “s=jω”, and the resistance value of the load circuit is defined as R. The impedance Z1 of the BOX capacitance alone is defined as “Z1=1/(sC_{BOX})”. Assuming that one end of the BOX capacitance is also connected to the potential point, when the well layer is connected to the potential point via a load circuit, the impedance Z2 of the well layer becomes a value obtained by connecting the parallel circuit of the capacitance C_{BOX} and the load circuit R in series with the capacitance C_{W}.

Therefore, if “sC_{BOX}>>1/R” is set, the value of 1/R can be ignored in the calculation of the impedance Z2. Therefore, substantially, the value Z2 is obtained by connecting the capacitance C_{BOX} in series to the capacitance C_{W}, and the value Z2 is “Z2=1/(sC_{BOX})+1/(sC_{W})”, and an expression of “Z2<Z1” is established. In this way, simply by adding a load circuit, the effect of the BOX capacitance (12) can be reduced and a decrease in the power conversion efficiency can be prevented.

According to the switched capacitor power source circuit of a second aspect of the present embodiments, a load circuit is connected to the well layers corresponding to all of the plurality of capacitance elements. This makes it possible to reduce the influence of the BOX capacitance for all the capacitance elements.

According to the switched capacitor power source circuit of a third aspect of the present embodiments, among a plurality of capacitance elements, the well layers corresponding to capacitance element groups having the same charging and discharging timing are connected to have the same potential, and a load circuit is connected to each capacitance element group. This makes it possible to reduce the number of load circuits, suppress an increase in circuit area, and suppress an increase in manufacturing costs.

### First Embodiment

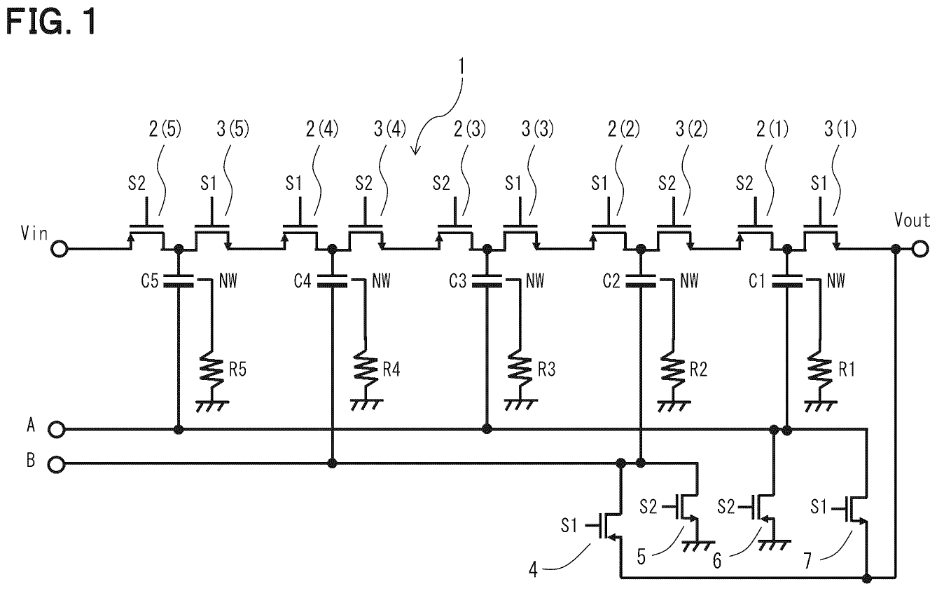

As shown in FIG. 1, a switched capacitor power source circuit 1 of this embodiment is of a Dickson type and is formed by an integrated circuit. Between the input terminal Vin and the output terminal Vout, for example, five sets of a P-channel MOSFET 2 and an N-channel MOSFET 3 connected in series are connected in series. S1 and S2 attached to the gates of the FETs 2 and 3 are the same clock signals as those shown in FIGS. 7A to 7C.

The top plates of the capacitance elements C1 to C5 are connected to the drains, which are the common connection points of the FETs 2 (1 to 5) and 3 (1 to 5). The bottom plates of the capacitance elements C2 and C4 are connected to the drains of a P-channel MOSFET 4 and an N-channel MOSFET 5, and the bottom plates of the capacitance elements C1, C3 and C5 are connected to the drains of a P-channel MOSFET 6 and an N-channel MOSFET 7. The sources of FETs 4 and 7 are connected to the output terminal Vout, and the sources of FETs 5 and 6 are connected to the ground. An N-well layer (i.e., NW layer) formed under the capacitance elements C1 to C5 is connected to the ground, which is also the substrate potential, via the resistance elements R1 to R5, respectively. The resistance element R, which is a passive element, is an example of a load circuit.

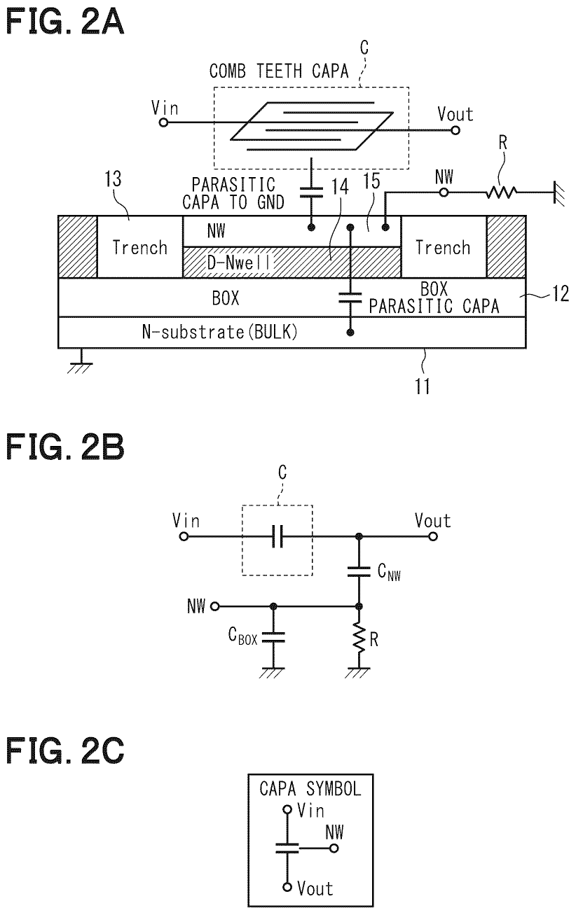

As shown in FIGS. 2A to 2C, a BOX layer 12 is formed on an N-type semiconductor substrate 11, and a deep N-well layer 14 and an N-well layer 15 are formed over the BOX layer 12 in a region separated by a trench 13 in which an insulator is buried. A capacitance element C is formed in the wiring layer, which is disposed on the surface of the N-well layer 15, by, for example, a comb-shaped electrode. In the drawings, Vin on the top plate side and Vout on the bottom plate side indicate the input side and output side of one capacitance element C. The N-well layer 15 is connected to the ground via a resistance element R formed in the wiring layer, and is therefore at the same potential as the semiconductor substrate 11.

With the above-described semiconductor configuration, as shown in the equivalent circuit in the drawings, the bottom plate of each capacitance element C is connected to the ground via the ground parasitic capacitance C_{NW} of the N-well layer 15 and a series circuit of a resistance element R. Furthermore, the common connection point of the capacitance C_{NW} and the resistance element R is connected to the ground via a BOX capacitance CBOX.

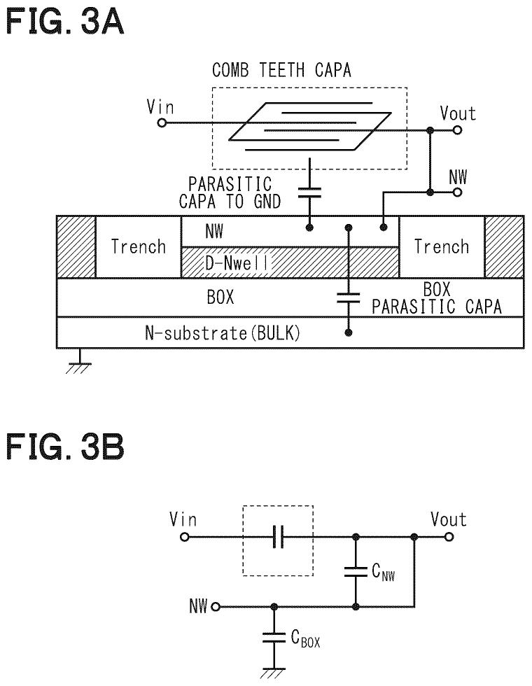

As shown in FIGS. 3A to 3B, in the capacitance element according to a comparison example, the N-well layer is directly connected to the bottom plate of the capacitance element, so that the ground parasitic capacitance C_{NW} is short-circuited. Therefore, the impedance Z1 of the N-well layer is obtained by an expression of “Z1=1/(sC_{BOX})” where “s=jω”.

In contrast to this, the impedance Z2 of the N-well layer 15 in the capacitance element C of this embodiment is given by an expression of “Z2=1/(sC_{BOX})+1/(sC_{W}+1/R)”.

Therefore, if “sC_{BOX}>>1/R” is set, the value of 1/R can be ignored in the calculation of the impedance Z2. Therefore, the impedance Z2 is substantially a value obtained by connecting the capacitance C_{BOX} in series with the capacitance C_{W}, that is, “Z2˜1/(sC_{BOX})+1/(sC_{W})”, so an expression of “Z2<Z1” is established.

This reduces the effect of the BOX capacitance and prevents a decrease in power conversion efficiency.

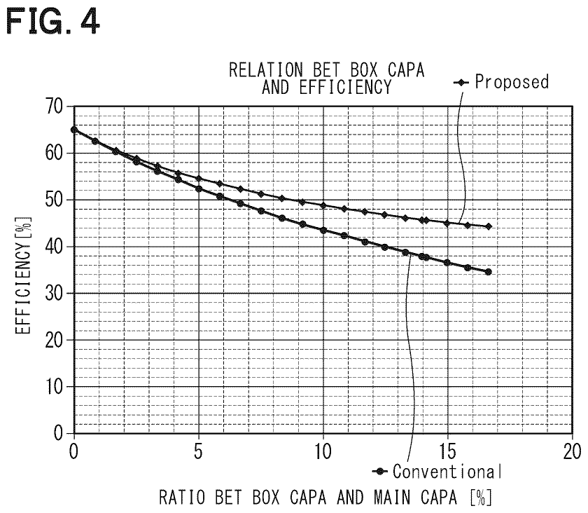

The results of the simulation are illustrated in FIG. 4. The horizontal axis represents the ratio of the BOX capacitance to the main capacitance, which is the capacitance of the capacitance element C itself. As this ratio increases, the power conversion efficiency of the switched capacitor power source circuit tends to decrease. In the comparison example configuration, the efficiency at the maximum ratio was 34.51%, whereas in the configuration of this embodiment, the efficiency increased to 44.22%, thus, confirming the effect of improving the power conversion efficiency.

As described above, according to this embodiment, in the switched capacitor power source circuit 1 formed of an integrated circuit, the N well layer 15 arranged under each of the capacitance elements C1 to C5 is connected to a potential point that is the same as the potential of the semiconductor substrate 11 via the resistance element R. In this way, simply by adding the resistance element R, the effect of the BOX capacitance can be reduced and a decrease in power conversion efficiency can be prevented.

### Second Embodiment

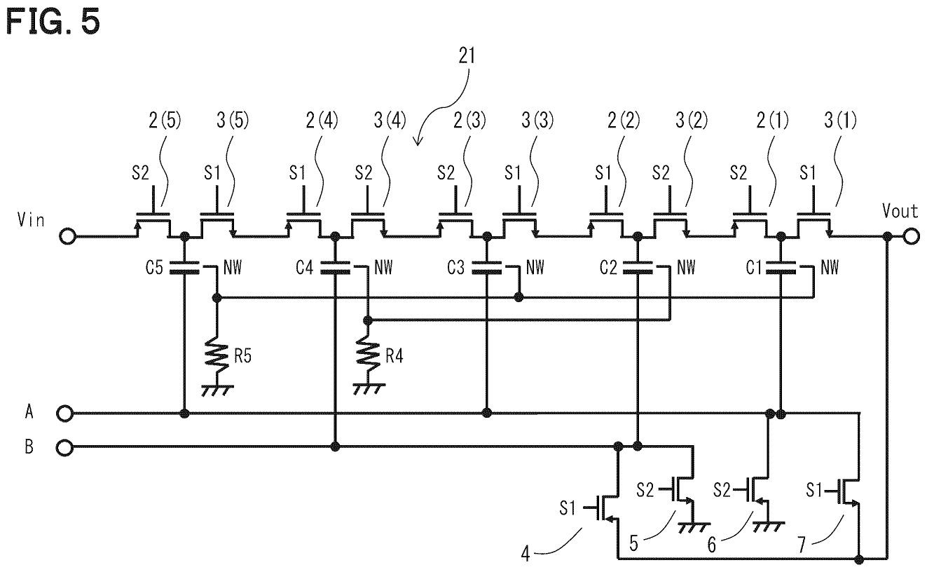

Hereinafter, the identical parts as those in the first embodiment will be designated by the same reference numerals for simplification of the description. Only differences from the first embodiment will be described below. In a switched capacitor power source circuit 21 according to the second embodiment shown in FIG. 5, the resistance elements R1 to R3 are omitted. The upper end of the resistance element R4 is commonly connected to the N well layers 15 corresponding to the capacitance elements C2 and C4, and the upper end of the resistance element R5 is commonly connected to the N well layers 15 corresponding to the capacitance elements C1, C3, and C5.

That is, the capacitance elements C1, C3, and C5, and the capacitance elements C2 and C4 are charged and discharged by clock signals having the same phase, respectively. Therefore, the potentials of the corresponding N-well layers 15 can be made common, so that the resistance elements can be reduced to only R4 and R5.

### Third Embodiment

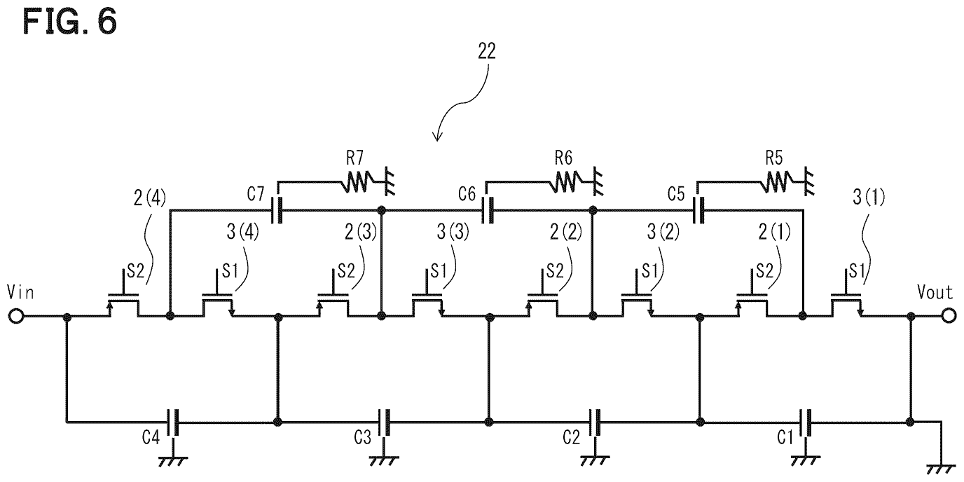

A switched capacitor power source circuit 22 according to the third embodiment shown in FIG. 6 is applied to a LADDER type 4:1 step-down converter, and the set of FETs 2 and 3 connected in series is, for example, four sets connected in series. A capacitance element C7 is connected between the drains of FET 2(4) and FET 3(4) and the drains of FET 2(3) and FET 3(3). A capacitance element C6 is connected between the drains of FET 2(3) and FET 3(3) and the drains of FET 2(2) and FET 3(2). A capacitance element C5 is connected between the drains of FET 2(2) and FET 3(2) and the drains of FET 2(1) and FET 3(1). The N-well layers corresponding to the capacitance elements C5 to C7 are connected to the ground via the resistance elements R5 to R7, respectively.

The third embodiment configured as above can also be applied to the LADDER type switched capacitor power source circuit 22.

The present embodiments include the following features.

Feature 1: A switched capacitor power source circuit includes an integrated circuit for converting an input voltage into a predetermined output voltage by charging and discharging a plurality of capacitance elements (C1 to C5) via a plurality of switching elements (2 to 7) using a plurality of clock signals with different phases. A well layer (15) disposed under each of the capacitance elements is connected via a load circuit (R) to a point of potential equal to or lower than a potential of a semiconductor substrate (11) constituting the integrated circuit.

Feature 2: In the switched capacitor power source circuit according to the feature 1, the load circuit is connected to the well layers corresponding to all of the plurality of capacitance elements.

Feature 3: In the switched capacitor power source circuit according to the feature 1 or 2, among the plurality of capacitance elements, the well layers corresponding to a capacitance element group having a same timing for charging and discharging are wired to have a same potential; and the load circuit is connected to each capacitance element group.

Feature 4: In the switched capacitor power source circuit according to any one of the features 1 to 3, the load circuit is a passive element disposed in a wiring layer.

### OTHER EMBODIMENTS

In each embodiment, the number of FETs 2 and 3 connected in series may be changed as appropriate according to the individual design. In addition, the present embodiments can also be applied to a series-parallel type. The well layer may be a P-well layer, in which case the semiconductor substrate should also be of P type. The electrode shape of the capacitance element is not limited to the comb-tooth shape. The load circuit may be a polysilicon resistance element, a metal resistance element, or a reverse-connected diode, or any other passive element having at least a resistance component. The potential of the potential point to which the load circuit is connected may be lower than the potential of the semiconductor substrate. The switching element may not be limited to a MOSFET.

Although the present disclosure has been made in accordance with the embodiments, it is understood that the present disclosure is not limited to such embodiments and structures. The present disclosure includes various modifications or deformations within an equivalent range. In addition, while the various combinations and configurations, which are preferred, other combinations and configurations, including more, less or only a single element, are also within the spirit and scope of the present disclosure.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations, other combinations and configurations, including more, less or only a single element, are also within the spirit and scope of the present disclosure.

What is claimed is:

1. A switched capacitor power source circuit comprising:
an integrated circuit for converting an input voltage into a predetermined output voltage by charging and discharging a plurality of capacitance elements via a plurality of switching elements using a plurality of clock signals with different phases, wherein:
a well layer disposed under each of the capacitance elements is connected via a load circuit to a point of potential equal to or lower than a potential of a semiconductor substrate constituting the integrated circuit.

2. The switched capacitor power source circuit according to claim 1, wherein:
the load circuit is connected to well layers corresponding to all of the plurality of capacitance elements.

3. The switched capacitor power source circuit according to claim 1, wherein:
among the plurality of capacitance elements, well layers corresponding to a capacitance element group having a same timing for charging and discharging are wired to have a same potential; and
the load circuit is connected to each capacitance element group.

4. The switched capacitor power source circuit according to claim 1, wherein:
the load circuit is a passive element disposed in a wiring layer.
